(19) United States
(12) Patent Application Publication
(10) Pub. No.: US 2008/0076034 A1
(43) Pub. Date: Mar. 27, 2008

(54) TRIM PHOTOMASK PROVIDING ENHANCED DIMENSIONAL TRIMMING AND METHODS FOR FABRICATION AND USE THEREOF

(76) Inventors: Brent A. Anderson, Jericho, VT (US); Jed H. Rankin, South Burlington, VT (US)

Correspondence Address: SCULLY, SCOTT, MURPHY & PRESSER, P.C., 400 GARDEN CITY PLAZA, Suite 300, GARDEN CITY, NY, 11530, US

(21) Appl. No.: 11/531,315

(22) Filed: Sep. 13, 2006

(51) Int. Cl. G03F 1/00

(52) U.S. Cl. 430/4

(57) ABSTRACT

A trim mask is used in conjunction with an additional mask for forming a patterned photoresist layer while using a two-step two-mask photoexposure method. The trim mask is used after exposing a blanket photoresist layer with the other mask. The trim mask comprises a transparent substrate. The trim mask also comprises patterned opaque layer and an adjoining patterned attenuated layer located exposed adjoining the patterned opaque layer and coincident with a latent images formed using the additional mask. The trim mask assists in addressing location dependent critical dimension variability when forming a patterned photoresist layer from the blanket photoresist layer or for creating uniform sub-lithographic imaging not possible with conventional lithographic techniques, including alternating phase shift lithography.

### BACKGROUND

1. Field of the Invention

The invention relates generally to photomasks. More particularly, the invention relates to photomasks with enhanced performance.

2. Description of the Related Art

As semiconductor device technology has advanced, critical dimensional control of semiconductor features, such as gate electrodes, continues to be of prominent importance. In particular, gate electrode critical dimension typically has a considerable influence upon semiconductor circuit operating parameters.

Critical dimensions of semiconductor features, such as gate electrodes, may also vary as a function of a particular location of a gate electrode upon a semiconductor substrate. Such location dependent critical dimension variability may result from inhomogeneous photolithographic processes or apparatus, or alternatively inhomogeneous manufacturing processes or apparatus. Other sources of variability are not excluded.

Given that critical dimension control is significant within semiconductor structures, methods and apparatus for controlling critical dimension are clearly desirable. Particularly desirable are methods and apparatus that may be adapted to address location dependent variability in critically dimensioned semiconductor structures, such as gate electrodes.

With respect to critical dimension control in general, phase shift photomasks are desirable in semiconductor fabrication insofar as phase shift photomasks provide for enhanced resolution of latent patterns within photoexposed photoresist layers. Enhanced resolution when photoexposing a photoresist layer to form a latent pattern therein in turn provides for enhanced resolution of a patterned photoresist layer that is developed from the photoexposed photoresist layer. Enhanced resolution of a patterned photoresist layer in turn provides for the desired enhanced critical dimensional control when forming other patterned layers or structures (i.e., in particular gate electrodes) when using the patterned photoresist layer as a mask for subsequent processing.

Although phase shift photomasks provide critical dimensional control advantages within the semiconductor fabrication art, phase shift photomasks do not in general address the location dependent critical dimension variability concerns that are disclosed above.

Semiconductor and microelectronic structure dimensions are certain to continue to decrease. Due to the continued decreases in dimensions, critical dimension control, in particular with respect to location dependent critical dimension variability, is likely to continue to be of considerable importance. Thus, desirable are photolithographic methods and apparatus that provide enhanced critical dimensional control, in particular as related to location dependent critical dimension variability.

### SUMMARY OF THE INVENTION

The invention provides a trim mask, a method for fabricating the trim mask and a two-step and two-mask method for forming a patterned photoresist layer that includes the use of the trim mask in conjunction with another mask.

The trim mask (or second mask in a dual exposure mask set) in accordance with the invention includes a transparent substrate. The trim mask also includes a patterned attenuator layer located over the transparent substrate and coincident with a latent pattern formed within a photoresist layer while using the other photomask. The trim mask also includes a patterned opaque material layer located upon the patterned attenuator layer. A portion of the patterned attenuator layer is exposed adjoining the patterned opaque material layer.

A method for fabricating a trim photomask used with an other photomask in accordance with the invention includes patterning an opaque material layer within a mask blank including a layered structure including a transparent substrate, an attenuator layer located thereupon and the opaque material layer located thereupon to form a patterned opaque material layer that leaves exposed the attenuator layer. The attenuator layer is coincident with a latent pattern formed within a photoresist layer while using the other photomask. The method also includes further patterning of the attenuator layer to form a patterned attenuator layer exposed beneath and adjoining the patterned opaque material layer.

A method for forming a patterned photoresist layer while using a trim mask in accordance with the invention in conjunction with an other mask includes photoexposing a photoresist layer with a first photoexposure while using a first mask that provides a first latent image within a once photoexposed photoresist layer. The method also includes photoexposing the once photoexposed photoresist layer with a second photoexposure using a second mask that includes a transparent portion, an attenuated portion coincident with the first latent image and an opaque portion adjoining the attenuated portion to provide a second latent image within a twice photoexposed photoresist layer. The method also includes developing the twice photoexposed photoresist layer to form a patterned photoresist layer.

### BRIEF DESCRIPTION OF THE DRAWINGS

The objects, features and advantages of the invention are understood within the context of the Description of the Preferred Embodiment, as set forth below. The Description of the Preferred Embodiment is understood within the context of the accompanying drawings, which form a material part of this disclosure, wherein:

FIG. 1 to FIG. 4 show: (1) a pair of schematic plan-view diagrams illustrating patterns of an alternating phase shift mask and a trim mask used within a two-step two-mask process in accordance with the prior art; and (2) a pair of patterned positive photoresist layers that result from using the alternating phase shift mask alone, or the alternating phase shift mask in conjunction with the trim mask.

FIG. 5 to FIG. 7 show: (1) a pair of schematic plan-view diagrams illustrating patterns of an alternating phase shift mask and a trim mask used within a two-step two-mask process in accordance with an embodiment of the invention; and (2) a patterned positive photoresist layer resulting from using the two-step two-mask process.

FIG. 8 to FIG. 10 show: (1) a pair of schematic plan-view diagrams illustrating patterns of a binary mask and a trim mask used within a two-step two-mask process in accordance with another embodiment of the invention; and (2) a patterned positive photoresist layer resulting from using the two-step two-mask process.

FIG. 11 and FIG. 15 show a series of schematic cross-sectional diagrams illustrating the results of progressive stages in fabricating a trim mask in accordance with any of the embodiments of the invention.

### DESCRIPTION OF THE PREFERRED EMBODIMENT

The invention, which is directed towards: (1) a trim mask; (2) a method for fabrication thereof, and (3) a method for use thereof within a two-step two-mask process that uses an additional mask and the trim mask, is understood within the context of further description below. The further description below is understood within the context of the drawings described above. Since the drawings described above are intended to be used for illustrative purposes, they are not necessarily drawn to scale.

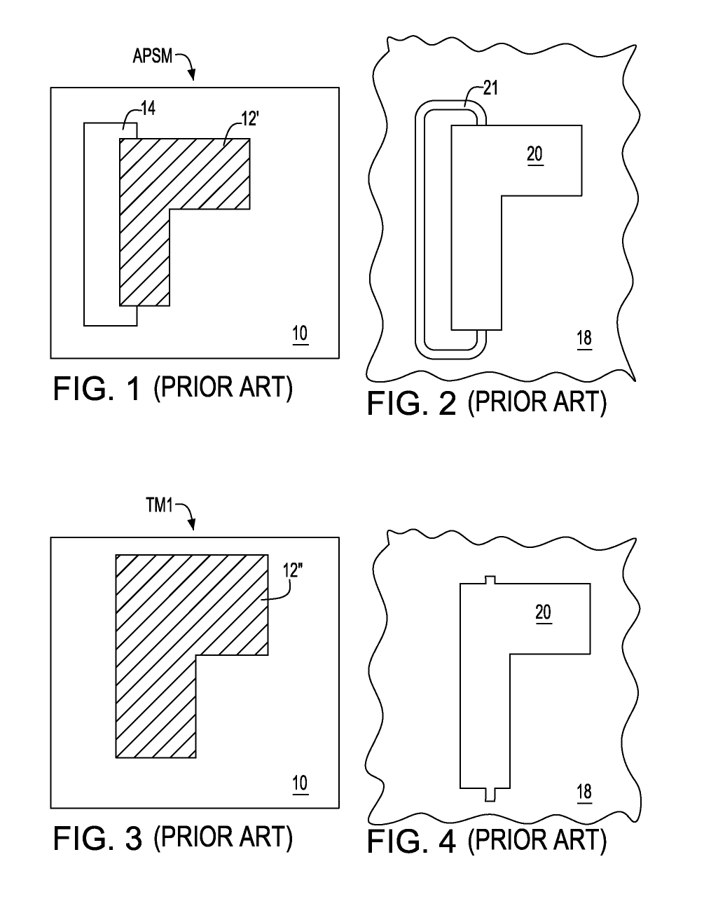

FIG. 1 to FIG. 4 show: (1) a pair of schematic plan-view diagrams illustrating patterns of an alternating phase shift mask and a trim mask used within a two-step two-mask process in accordance with the prior art; and (2) a pair of patterned positive photoresist layers that result from using the alternating phase shift mask alone, or the alternating phase shift mask in conjunction with the trim mask.

FIG. 1 shows the schematic plan-view diagram of the alternating phase shift mask APSM, and the pattern layout that comprises the alternating phase shift mask APSM.

FIG. 1 shows a transparent substrate 10. A patterned opaque layer 12′ is located and formed upon the transparent substrate 10. A transparent shifter layer 14 overlaps one side of the patterned opaque layer 12′.

The alternating phase shift mask APSM whose schematic plan-view diagram is illustrated in FIG. 1 comprises a generally conventional alternating phase shift mask APSM. Such a generally conventional alternating phase shift mask APSM uses the transparent shifter layer 14 on one side of the patterned opaque layer 12′, but not on the other side of the patterned opaque layer 12′. The transparent shifter layer 14 typically has a thickness equal to one-half of the photoexposure radiation wavelength used for photoexposing a photoresist layer while using the alternating phase shift mask APSM. Such a difference in an optical path length on one side of the patterned opaque layer 12′ and the other side of the patterned opaque layer 12′ provides for a reinforcing optical interference. The reinforcing optical interference yields a more highly resolved photoexposure radiation peak from the alternating phase shift mask APSM whose schematic plan-view diagram is illustrated in FIG. 1, in comparison with a generally conventional binary photomask (i.e., similar to the alternating phase shift mask APSM whose schematic plan-view diagram is illustrated in FIG. 1, but absent the transparent shifter layer 14).

An alternate method for fabricating an alternating phase shift mask APSM provides for removal of a portion of a transparent substrate region to produce the phase shifting result, rather than adding a transparent shifter layer thereupon.

In accordance with disclosure above, alternating phase shift photomasks provide generally sharper resolution photoexposure radiation. However, they also suffer from the deficiency that the presence of the transparent shifter layer 14 also provides for either: (1) spurious photoexposure radiation; or (2) inadequate photoexposure radiation, when photoexposing a photoresist layer when using an alternating phase shift photomask. Such spurious photoexposure radiation or inadequate photoexposure radiation in general compromises the enhanced resolution that is provided by use of the alternating phase shift mask APSM that includes the transparent shifter layer 14.

An example of the result of the spurious photoexposure radiation or inadequate photoexposure radiation is shown in the schematic cross-sectional diagram of FIG. 2. FIG. 2 shows the results of photoexposing and developing a blanket positive photoresist layer while using the alternating phase shift mask APSM whose schematic plan-view diagram is illustrated in FIG. 1.

FIG. 2 first shows a substrate 18. The substrate 18 may comprise a conductor material, a semiconductor material or a dielectric material. The substrate 18 may also comprise laminates thereof and composites thereof. FIG. 2 also shows a patterned positive photoresist layer 20 that results from photoexposing and developing a blanket positive photoresist layer. The patterned positive photoresist layer 20 has enhanced dimensional resolution due to photoexposure of the blanket positive photoresist layer while using the alternating phase shift mask APSM whose schematic plan-view diagram is illustrated in FIG. 1. However, due to the presence of the transparent shifter layer 14, use of the alternating phase shift mask APSM whose schematic plan-view diagram is illustrated in FIG. 1 also provides a residue layer 21. The residue layer 21 may result from diffraction of photoexposure radiation at the interface of the transparent substrate 10 and the transparent shifter layer 14.

When not removed prior to further processing, the residue layer 21 can create electrical shorts between intended lithographic features on the same level, or it may cause an inadvertent short to another level, such as a prior or a subsequently imaged layer. The extent of any particular impact will depend on how a “phase coloring” algorithm designs an alternating phase region when the algorithm converts originally designed data to alternating phase shift mask data.

In order to reduce or eliminate the residue layer 21 that is illustrated within the schematic plan-view diagram of FIG. 2, it is common to use a trim mask that provides for additional photoexposure radiation to portions of the photoresist structure of FIG. 2 that include the residue layer 21.

Such a trim mask is illustrated within the schematic plan-view diagram of FIG. 3.

In general, the trim mask TM1 also comprises a transparent substrate 10. The trim mask TM1 also comprises a patterned opaque layer 12″ located over the transparent substrate 10. The patterned opaque layer 12″ is generally larger than the patterned opaque layer 12′ that is illustrated within the alternating phase shift mask of FIG. 1, but it is located so that it does not entirely cover a portion where the transparent shifter layer 14 was located.

FIG. 4 shows the results of photoexposing and developing a positive photoresist layer after first photoexposing the positive photoresist layer while using the alternating phase shift mask APSM of FIG. 1 and then the trim mask TM1 of FIG. 3.

As is illustrated in FIG. 4, the patterned photoresist layer 20 is still present. However, the residue layer 21 is no longer present due to the additional dose of photoexposure radiation that is provided by the trim mask TM1 that is illustrated in FIG. 3.

As is understood by a person skilled in the art, the foregoing disclosure within the context of the alternating phase shift mask APSM of FIG. 1, the trim mask TM1 of FIG. 3 and the resulting patterned photoresist layers of FIG. 2 and FIG. 4 is explicitly directed towards photoexposure of a positive photoresist layer to form the patterned positive photoresist layer 20. However, the invention is not necessarily limited to only photoexposure of a positive photoresist layer. Rather, the invention also contemplates use of a photoresist layer comprising a negative photoresist material or a hybrid photoresist material (having both positive photoresist characteristics and negative photoresist characteristics). Different types of spurious radiation effects may be anticipated with negative photoresist materials and hybrid photoresist materials in comparison with positive photoresist materials. Different types of spurious radiation effects may also be anticipated with different types of masks. For that reason, phase shift masks and trim masks that are used with negative photoresist materials and hybrid photoresist materials may have differing types, sizes and locations of patterns.

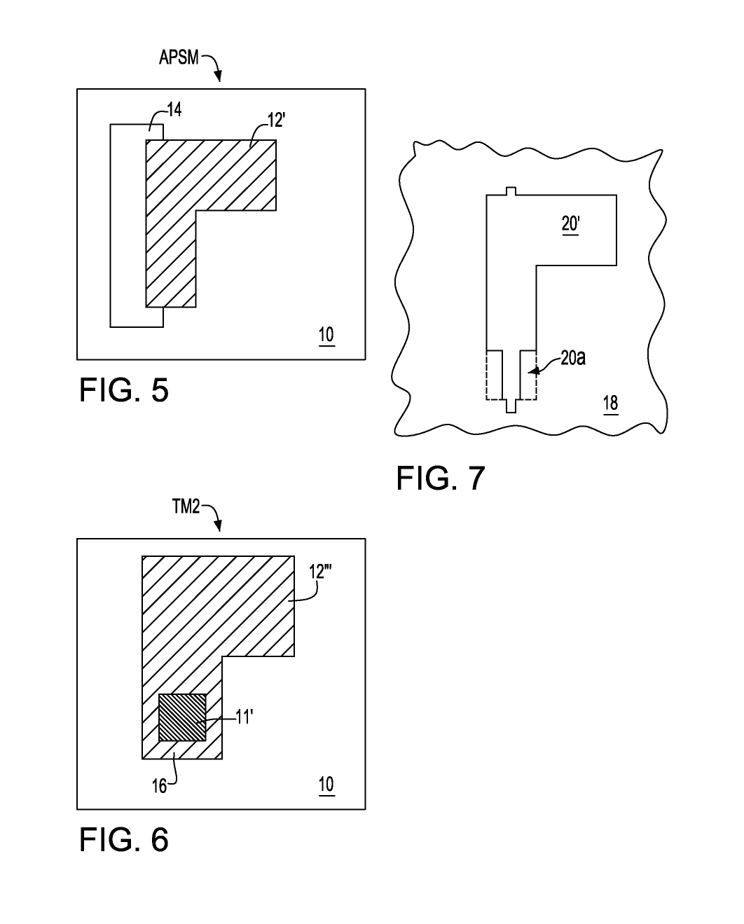

FIG. 5 to FIG. 7 show: (1) a pair of schematic plan-view diagrams illustrating patterns of an alternating phase shift mask APSM and a trim mask TM2 used within a two-step two-mask process in accordance with the invention; and (2) a resulting pattern of a patterned positive photoresist layer resulting from the two-step two-mask process.

FIG. 5 shows a schematic plan-view diagram of an alternating phase shift mask APSM that is identical to the alternating phase shift mask APSM whose schematic plan-view diagram is illustrated in FIG. 1. The alternating phase shift mask APSM uses the same transparent substrate 10. The patterned opaque layer 12′ and the transparent shifter layer 14 are of identical dimensions and located in identical positions upon the transparent substrate 10.

FIG. 6 shows a schematic plan-view diagram of a trim mask TM2 in accordance with the invention. The trim mask TM2 may be used in the alternative of the trim mask TM1 whose schematic plan-view diagram is illustrated in FIG. 3.

The trim mask TM2 whose schematic plan-view diagram is illustrated in FIG. 6 also uses a transparent substrate 10. The trim mask TM2 whose schematic plan-view diagram is illustrated in FIG. 6 also uses a patterned opaque layer 12′″ of projected dimensions that are the same as the projected dimensions of the patterned opaque layer 12″ that is illustrated in the trim mask TM1 of FIG. 3. However, the trim mask TM2 whose schematic plan-view diagram is illustrated in FIG. 6 further comprises an aperture 16 which exposes a portion of an attenuator layer 11′. The exposed portion of the attenuator layer 11′ is coincident with a latent image within a photoresist layer exposed using the alternating phase shift mask APSM of FIG. 5. The portion of the attenuator layer 11′ may in addition be patterned. Thus, a trim mask TM2 in accordance with the invention is typically not a binary mask as a trim mask TM1 is in accordance with the schematic plan-view diagram of FIG. 3. Rather, the trim mask TM2 comprises a ternary mask that comprises the portion of the attenuator layer 11′ in addition to a transparent substrate 10 and the patterned opaque layer 12′″. Generally, the attenuator layer attenuates from about 80 to about 95% of photoexposure radiation (i.e., has a transmittance from about 5 to about 20%). The portion of the attenuator layer 11′ while exposed within the window 16 may in an alternative also simply extend laterally from underneath a portion of the patterned opaque layer 12′″. Under such circumstances, the attenuator layer is not completely bounded by the patterned opaque material layer 12′″, but rather simply adjoins the patterned opaque material layer 12′″.

FIG. 7 shows a schematic plan-view diagram of a patterned positive photoresist layer that may be formed upon a substrate in accordance with sequential photoexposure while using the alternating phase shift mask APSM whose schematic plan-view diagram is illustrated in FIG. 5 followed by the trim mask TM2 whose schematic plan-view diagram is illustrated in FIG. 6.

FIG. 7 again shows the substrate 18. A patterned positive photoresist layer 20′ is located upon the substrate 18.

As is illustrated in FIG. 7, the patterned positive photoresist layer 20′ is formed with a narrower bottom end portion 20a in comparison with the patterned positive photoresist layer 20 that is illustrated in FIG. 4.

The narrowed bottom end portion 20a of the patterned photoresist layer 20′ results from the presence of the window 16 within the patterned opaque layer 12′″, and also the presence of the portion of the attenuator layer 11 exposed within the window 16. This region receives a “dual exposure” where the primary image is formed as a latent image in the photoresist during the first exposure, then the dimensions are slightly modified by delivering a sub-threshold dose during the second exposure. This sub-threshold dose is achieved by using the portion of the attenuator layer 11′ which allows for transmission of a dose lower than the minimum dose available on the photolithographic tool used.

Thus, a trim mask TM2 in accordance with the embodiment provides for an additional shaping and shrinking of a desired patterned positive photoresist layer 20′ in comparison with the patterned positive photoresist layer 20 whose schematic plan-view diagram is illustrated in FIG. 4. This additional shaping may be useful within the context of compensating for a location dependent variation in critical dimension of the patterned photoresist layer 20 that is illustrated in FIG. 4. Location dependent critical dimension variations are disclosed in further detail within the background.

The instant embodiment of the invention that is illustrated in FIG. 5 to FIG. 7 uses a trim mask TM2 with a modification 16 in comparison with a trim mask TM1 generally in accordance with the prior art as illustrated in FIG. 2. Either trim mask TM1 or trim mask TM2 is used with the same alternating phase shift mask APSM. The alternating phase shift mask APSM in general requires the use of a trim mask to provide a desired final patterned photoresist layer. Substitution of the trim mask TM2 for the trim mask TM1 provides a means for providing a variation of a critical dimension of a patterned photoresist layer (or a further underlying patterned layer) under circumstance where the variation of the critical dimension of the patterned photoresist layer is not otherwise photolithographically resolvable.

The minimum dimension photolithographically achievable is based on several factors, including the optics of the photolithographic projector, the chemical reaction occurring in the photoresist, and wavelength of radiation used. Due to inherent variations in the tools used, and a finite ability to control the environment, it is generally required that the process is established to operate within reasonable bounds, including temperatures, doses, focal positions, etc. The magnitude of the assumed variability also limits the photolithographically achievable dimensions. The feature size and density, thus overall semiconductor chip size and performance rate, are limited by the minimum achievable lithographic image size. It is often desirable to create images that are “sub-lithographic” yet still controlled to a high degree of precision. The technique and structures described in the embodiment and the invention allow for reliable fabrication of sub-lithographic shapes on all or some features in a design. This can be used to either compensate for location dependent variation or to achieve consistent sub-lithographic imaging.

While the use of a modified trim mask TM2 in accordance with the instant embodiment provides a desirable application of the invention, the invention is clearly not limited to situations where a trim mask is used only in conjunction with an alternating phase shift mask. Rather, the invention also contemplates situations where a trim mask is also used within a two-step two-mask process that includes photomasks other than phase shift photomasks, and phase shift photomasks other than alternating phase shift photomasks.

In accord with the above, a salient feature of the invention is that it allows a technique of using a sub-threshold dose to be delivered on a second mask in accordance with other dual-mask procedures while not requiring the use of a third mask.

There are various “dual exposure” techniques. A particularly promising technique uses deconstruction of a design based on orientation. In this method, all horizontal features are printed with a first mask, then all vertical features are printed with a second mask. Other techniques include printing only every other line, so that the “pitch” is more relaxed during lithography. A third technique commonly used is to print all features as “dense” or in a tight pitch (with appropriate lithographic conditions). Then with a second mask, all unwanted features, or portions of features are removed.

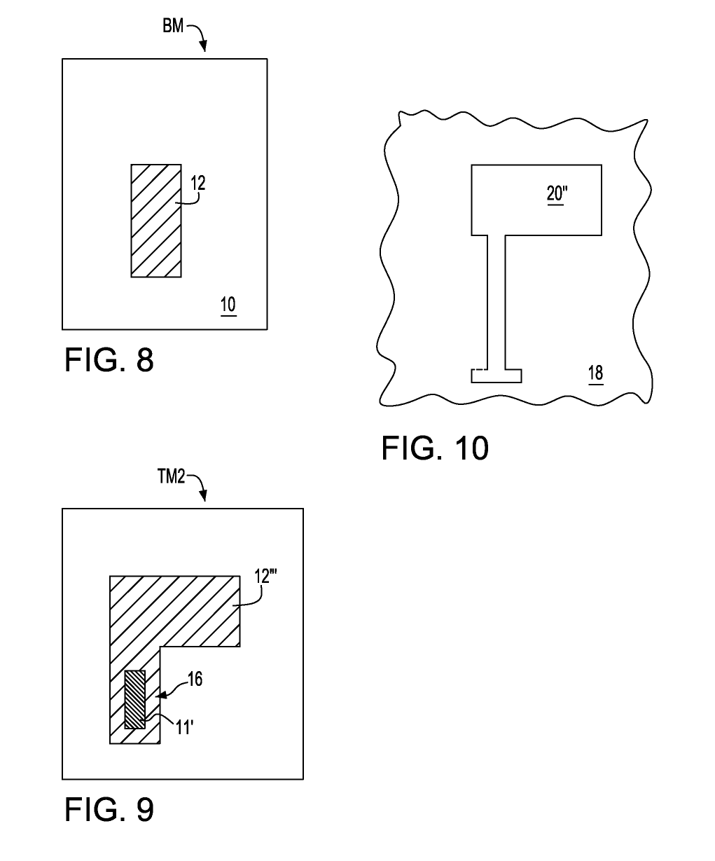

FIG. 8 to FIG. 10 show: (1) a pair of schematic plan-view diagrams illustrating patterns of a binary mask and a trim mask used within a two-step two-mask process in accordance with another embodiment of the invention; and (2) a patterned positive photoresist layer resulting from using the two-step two-mask process.

FIG. 8 shows a schematic plan-view diagram of the binary mask BM. The binary mask BM comprises a transparent substrate 10 and a patterned opaque layer 12.

The trim mask TM2 that is illustrated within the schematic plan-view diagram of FIG. 9 may be identical or may be generally related to the trim mask TM2 that is illustrated in FIG. 3 within the first embodiment.

FIG. 10 shows a structure related to FIG. 7. FIG. 10 shows a patterned positive photoresist layer 20″ located upon the substrate 18. A difference between the patterned positive photoresist layer 20′ that is illustrated in FIG. 7 and the patterned positive photoresist layer 20″ that is illustrated in FIG. 10 relates to less critical dimensional control of the patterned positive photoresist layer 20″ within the structure of FIG. 10, since the initial photoexposure of a blanket positive photoresist layer is not undertaken with an alternating phase shift photomask APSM, but rather with a binary mask BM. This embodiment of the invention uses a bright field mask, some of whose regions have 100% transmission.

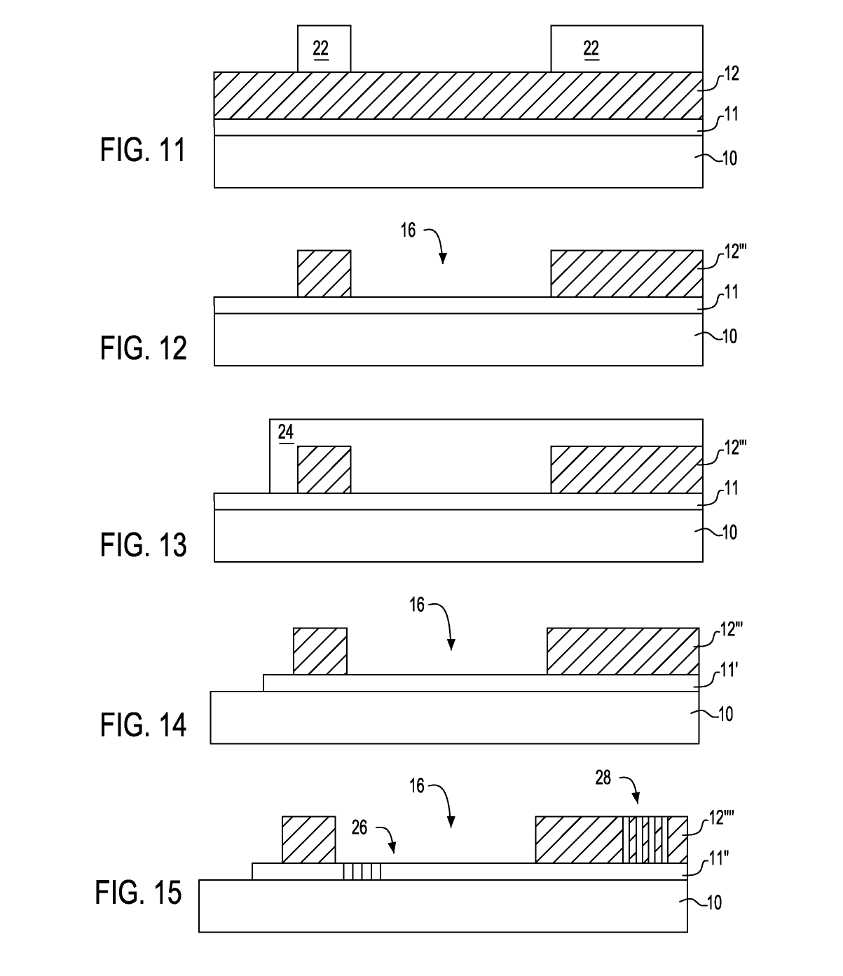

FIG. 11 to FIG. 15 show a series of schematic cross-sectional diagrams illustrating the results of progressive stages in fabricating a trim mask that is used in accordance with the foregoing embodiments of the invention.

FIG. 11 shows a schematic cross-sectional diagram of the trim mask at an early stage in the fabrication thereof.

FIG. 11 shows the transparent substrate 10. An attenuator layer 11 is located upon the transparent substrate 10. An opaque layer 12 is located upon the attenuator layer 11. Patterned photoresist layers 22 are located upon the opaque layer 12.

The transparent substrate 10 may comprise any of several transparent materials. Non-limiting examples of transparent materials include quartz materials and glass materials. Quartz is generally a more common transparent substrate material for a photomask, but the invention is not limited to a transparent substrate 10 that comprises a quartz material. Typically the transparent substrate 10 has a thickness from about 100 to about 200 mils.

The attenuator layer 11 comprises an attenuator material. Typical attenuator materials include molybdenum silicide materials, molybdenum oxide materials, amorphous carbon materials and silicon oxide/silicon nitride laminate materials. The attenuator material typically attenuates from about 80 to about 95 percent of incoming photoexposure radiation. Molybdenum silicide compositions typically attenuate about 94 percent of incoming photoexposure radiation (i.e., 6% transmission). The attenuator material may be formed using any of several methods that are appropriate to its material of composition. Non-limiting examples of methods include thermal or plasma oxidation or nitridation methods, chemical vapor deposition methods (including atomic layer chemical vapor deposition methods) and physical vapor deposition methods (including sputtering methods). Typically, the attenuator material has a thickness from about 200 to about 500 angstroms.

The opaque material layer 12 comprises an opaque material that is typically an opaque conductor material. Although other opaque conductor materials may also be used, the opaque material layer 12 most commonly comprises a chromium opaque conductor. Use of opaque material other than opaque conductor materials is not excluded within the invention, but is also not particularly common with the photomask art. The opaque material may be deposited using any of several methods that are conventional in the art. Plating methods, chemical vapor deposition methods and physical vapor deposition methods are common methods. A sputtering method as a variation of a physical vapor deposition method is a common method. Typically, a chromium opaque conductor material 12 is sputter deposited to a thickness from about 300 to about 1500 angstroms.

The photoresist layers 22 may comprise any of several photoresist materials. Non-limiting examples include positive photoresist materials, negative photoresist materials and hybrid photoresist materials. Typically, the photoresist layers are formed using conventional spin coating, photoexposure and development methods to provide the photoresist layers of thickness from about 10000 to about 20000 angstroms.

FIG. 12 shows a schematic cross-sectional diagram that illustrates the results of patterning the opaque material layer 12 to form the patterned opaque material layer 12′″ that define the window 16 (corresponding generally with FIG. 6). The patterning is effected using the photoresist layers 22 as a mask. The patterning may be effected using etch methods including but not limited to: wet chemical etch methods and dry plasma etch methods. Both of the foregoing methods are particularly common.

FIG. 13 shows a photoresist layer 24 located upon the mask structure of FIG. 12. The photoresist layer 24 in FIG. 13 is otherwise analogous of equivalent to the photoresist layers 22 in FIG. 1, but located so that a portion of the attenuator layer 11 is exposed.

FIG. 14 shows the results of further patterning of the attenuator layer 11 to form the attenuator layer 11′, while using the photoresist layer 24 as a mask. The patterning is typically effected while using a etch method that uses an etchant material that is appropriate to the materials from which is formed attenuator layer 11. Wet chemical etchant materials and dry plasma etchant materials may be used. Dry plasma etchant materials are typically more common.

FIG. 15 shows a schematic cross-sectional diagram illustrating the results of further processing of the trim mask of FIG. 14. FIG. 15 shows the results of additional patterning of both the patterned opaque layer 12′″ (indicated by structures corresponding with reference numeral 26) to provide patterned opaque layer 12″″ and the patterned attenuator layer 11′ (indicated by structures corresponding with reference numeral 28) to provide the patterned attenuator layer 11″. The additional patterning of the patterned opaque layer 12′″ and the patterned attenuator layer 11′ is effected sub-lithographically (i.e., sub-lithographic is intended as comprising dimensions <½ the wavelength of a photoexposure radiation being used) while typically using an electron beam, ion beam or laser beam irradiation method. The patterned attenuator layer 11″ need not necessarily be completely patterned. The additional patterning of the patterned opaque layer 12′″ to form the patterned opaque layer 12″″ and the patterned attenuator layer 11′ to form the patterned attenuator layer 11″ provides additional processing variability and tuning of the photomask of FIG. 15 (i.e., the additional patterning provides for gray scale imaging).

FIG. 15 shows a schematic cross-sectional diagram of a trim mask that may be used in accordance with the embodiments of the invention. The trim mask comprises a transparent substrate 10, a patterned attenuator layer 11″ located thereupon and a patterned opaque layer 12″″ located further thereupon. A portion of the patterned attenuator layer 11″ is exposed within a window 16 within the patterned opaque layer 12″″. An additional portion of the patterned attenuator layer 11″ extends beyond the window 16 and is exposed beneath the patterned opaque layer 12″″.

Portions of both the patterned opaque layer 12″″ and the patterned attenuator layer 11″ are further patterned with sub-lithographic resolution to provide enhanced optical tuning of the trim mask whose schematic cross-sectional diagram is illustrated in FIG. 15.

The trim mask whose schematic cross-sectional diagram is illustrated in FIG. 15 provides value insofar as it assists in providing enhanced critical dimension control, in particular with respect to a location dependent variability of critical dimension, for a patterned photoresist layer formed using a two-step two-mask method that includes the trim mask. In turn, such location dependent critical dimension control for a patterned photoresist layer also provides for location dependent critical dimension control for a layer or a structure that is formed using the patterned photoresist layer as a mask. Such a patterned layer or a patterned structure may in particular include a gate electrode.

The preferred embodiments of the invention are illustrative of the invention rather than limiting of the invention. Revisions and modifications may be made to methods, materials structures and dimensions of a trim mask in accordance with the preferred embodiments of the invention while still providing a trim mask, a method for fabrication thereof and a method for use thereof in accordance with the embodiments and the invention, further in accordance with the accompanying claims.

What is claimed is:

1. A trim photomask used with an other photomask comprising:
a transparent substrate;
a patterned attenuator layer located over the transparent substrate and coincident with a latent pattern formed within a photoresist layer while using the other photomask; and
a patterned opaque material layer located upon the patterned attenuator layer, a portion of the patterned attenuator layer being exposed adjoining the patterned opaque material layer.

2. The photomask of claim 1 wherein the portion of the patterned attenuator layer exposed adjoining the patterned opaque material layer is completely surrounded by the patterned opaque material layer.

3. The photomask of claim 1 wherein the portion of the patterned attenuator layer exposed adjoining the patterned opaque material layer is not completely surrounded by the patterned opaque material layer.

4. The photomask of claim 1 wherein the patterned attenuator layer comprises a molybdenum silicide.

5. The photomask of claim 1 wherein the patterned attenuator layer has a transmittance of from about 5 to about 20 percent.

6. The photomask of claim 1 wherein the patterned opaque material layer comprises a patterned chrome material.

7. The photomask of claim 1 wherein at least one of the patterned opaque material layer and the patterned attenuator layer comprises an optical sub-lithographic feature.

8. A method for fabricating a trim photomask used with an other photomask comprising:
patterning an opaque material layer within a mask blank comprising a layered structure comprising a transparent substrate, an attenuator layer located thereupon and the opaque material layer located thereupon to form a patterned opaque material layer that leaves exposed the attenuator layer, the attenuator layer being coincident with a latent pattern formed within a photoresist layer while using the other photomask; and
further patterning the attenuator layer to form a patterned attenuator layer exposed beneath and adjoining the patterned opaque material layer.

9. The method of claim 8 wherein the further patterning uses a direct writing of a photoresist layer, followed by development thereof and use as an etch mask.

10. The method of claim 9 wherein the direct writing uses a laser writing.

11. The method of claim 9 wherein the direct writing uses an ion writing.

12. The method of claim 9 wherein the direct writing uses an electron beam writing.

13. The method of claim 8 wherein the pattering uses the mask blank that comprises a transparent quartz substrate, a molybdenum silicide attenuator layer located thereupon and a chromium opaque material layer located thereupon.

14. A method for forming a patterned photoresist layer comprising:
photoexposing a photoresist layer with a first photoexposure while using a first mask that provides a first latent image within a once photoexposed photoresist layer;
photoexposing the once photoexposed photoresist layer with a second photoexposure using a second mask that comprises a transparent portion, an attenuated portion coincident with the first latent image and an opaque portion adjoining the attenuated portion to provide a second latent image within a twice photoexposed photoresist layer; and
developing the twice photoexposed photoresist layer to form a patterned photoresist layer.

15. The method of claim 14 wherein the photoexposing the photoresist layer uses an alternating phase shift mask as the first mask.

16. The method of claim 14 wherein the photoexposing the photoresist layer uses other than an alternating phase shift mask as the first mask.

17. The method of claim 14 wherein the photoexposing the photoresist layer uses a positive photoresist material.

18. The method of claim 14 wherein the photoexposing the once photoexposed photoresist layer with the second photoexposure using the second mask that comprises the attenuated portion coincident with the first latent image provides for a shrinking of a portion of the patterned photoresist layer corresponding with the attenuated portion.

19. The method of claim 14 wherein the opaque portion is patterned with a sublithographic feature.

20. The method of claim 14 wherein the attenuated portion is patterned with a sublithographic feature.

21. The method of claim 14 wherein the attenuated portion is patterned with a sublithographic feature that is not formed completely through the attenuated portion.
